(19) United States
(12) Patent Application Publication
(10) Pub. No.: US 2023/0091972 A1
(43) Pub. Date: Mar. 23, 2023

(54) SEMICONDUCTOR DISK LASERS WITH MICROSTRUCTURES

(71) Applicant: TRUMPF SE + Co. KG, Ditzingen (DE)

(72) Inventors: Cunzhu Tong, Jilin (CN); Guanyu Hou, Jilin (CN); Lijie Wang, Jilin (CN); Sicong Tian, Jilin (CN); Lijun Wang, Jilin (CN); Andreas Popp, Markgroeningen (DE); Berthold Schmidt, Stuttgart (DE)

(21) Appl. No.: 18/056,733

(22) Filed: Nov. 18, 2022

Related U.S. Application Data
(63) Continuation of application No. PCT/EP2021/062247, filed on May 10, 2021.

(30) Foreign Application Priority Data
May 19, 2020 (CN) 202010427842.0

(51) Int. Cl. H01S 5/187; H01S 5/10

(52) U.S. Cl. CPC H01S 5/187; H01S 5/1075

(57) ABSTRACT

A semiconductor disk chip includes a cap layer having at least one structured region for mode selection, a periodic gain structure, a Distributed Bragg reflector, and a substrate. The structured region is structured in such a way that a lateral fundamental mode of the laser radiation experiences lower losses than radiation of higher laser modes and includes at least one trench extending into the cap layer to a depth not greater than a thickness of the cap layer, and wherein the depth decreases from an outer region of an emission surface of the semiconductor chip in a direction of an inner of the emission surface of the semiconductor chip.

### CROSS REFERENCE TO RELATED APPLICATIONS

This application is a continuation of International Application No. PCT/EP2021/062247 (WO 2021/233701 A1), filed on May 10, 2021, and claims benefit to Chinese Patent Application No. CN 202010427842.0, filed on May 19, 2020. The aforementioned applications are hereby incorporated by reference herein.

### FIELD

This invention relates to a semiconductor disk laser.

### BACKGROUND

Semiconductor disk lasers having high output powers are demanded in many fields. The amplification of the optical field takes place in an active layer, which contains a quantum well structure, for example. And the performance of the semiconductor disk laser is limited by the power density of the laser modes in the facet region.

By virtue of increasing the area of the optical pump without lowering the power density, a high optical power can be realized from the semiconductor disk laser. However, the number of transverse modes which can be amplified in the region of the emission surface of the semiconductor chip also increases, which results in a deterioration in the beam quality of the laser radiation coupled out.

For most applications of semiconductor disk lasers, operation in the transverse fundamental mode (single-mode laser) is desired since the intensity profile of the lateral fundamental mode facilitates beam shaping. Moreover, the maximum power of the semiconductor disk laser can be increased in this case since the fundamental mode typically has no pronounced intensity peaks.

### SUMMARY

In an embodiment, the present disclosure provides a semiconductor disk chip including a cap layer having at least one structured region for mode selection, a periodic gain structure, a Distributed Bragg reflector, and a substrate. The structured region is structured in such a way that a lateral fundamental mode of the laser radiation experiences lower losses than radiation of higher laser modes and includes at least one trench extending into the cap layer to a depth not greater than a thickness of the cap layer, and wherein the depth decreases from an outer region of an emission surface of the semiconductor chip in a direction of an inner of the emission surface of the semiconductor chip

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIGS. 1A and 1B show a semiconductor disk chip in accordance with a first exemplary embodiment in a cross section and in a plan view;

FIGS. 2A and 2B show an exemplary embodiment of a method for producing a semiconductor disk chip on the basis of schematically illustrated intermediate steps;

FIGS. 3A, 3B and 3C show the structured region in a further exemplary embodiment of the semiconductor disk chip in a plan view and in sectional illustrations; and

FIGS. 4A and 4B show the structured region in a further exemplary embodiment of the semiconductor disk chip in a plan view and in sectional illustrations.

### DETAILED DESCRIPTION

In one aspect, the invention specifies an improved semiconductor disk laser which is distinguished by a high beam quality, in particular, operation in the lateral fundamental mode.

In accordance with one embodiment, the semiconductor disk laser, contains a semiconductor disk chip having a cap layer. The cap layer has at least one structured region for mode selection. The structured region is structured in such a way that the lateral fundamental mode of the laser radiation experiences lower losses than the radiation of higher laser modes. On account of the structured region, the laser radiation which traverse through the cap layer experiences local losses, wherein the structured region is formed in such a way that higher laser modes are damped to a greater extent than the lateral fundamental mode. What can be achieved in this way, in particular, is that only the lateral fundamental mode commences oscillation during the operation of the semiconductor laser.

By virtue of the fact that higher modes of the laser radiation are suppressed and preferably only the lateral fundamental mode commences oscillation, a high beam quality of the semiconductor disk laser is obtained. Furthermore, in this way, intensity peaks at the side facet of the semiconductor laser at which the radiation is coupled out are reduced, such that a high output power can be obtained with the semiconductor laser.

The at least one structured region is preferably formed exclusively in the cap layer. In particular, the structured region does not extend right into the active layer of the semiconductor disk chip, the active layer being formed, for example, as a single or multiple quantum well structure.

In one preferred embodiment, the structured region comprises at least one trench which is preferably only formed in the cap layer, that is to say that its depth is not greater than the thickness of the cap layer.

The width of the at least one trench is preferably between 1 μm and 4 μm inclusive. The at least one trench can be produced, for example, by means of an etching process in the semiconductor material of the cap layer.

Upon traversing the trench, the laser radiation experiences scattering losses in each case upon entering into the trench at a first trench and upon exiting from the trench at a second trench. The laser radiation is advantageously damped by less than ten percent, preferably by less than five percent, during a passage through the trench. By way of example, a loss of approximately two percent can occur when a trench is traversed. The magnitude of the loss experienced by the laser radiation upon traversing the trench is dependent, in particular, on the form and the depth of the trench and also, in the case of a plurality of trenches, on the number of trenches.

In one advantageous configuration, at least one trench extend from outer regions of the emission surface of the semiconductor chip into the inner of the emission surface of the semiconductor chip with the same centroid but with different extents. The outer concentric patterns have the largest extents. The inner concentric patterns are larger than the size of the fundamental mode on the surface of the semiconductor chip. In this case, the region of the fundamental mode on the surface of the semiconductor chip is free of trenches. What can be achieved in this way is that higher transverse laser modes which propagate at the outer regions of the emission surface of the semiconductor chip experience higher losses than the transverse fundamental mode having an intensity maximum in the inner of the emission surface of the semiconductor chip.

In a further advantageous configuration, a multiplicity of trenches extends from an outer region of the emission surface of the semiconductor chip into the inner of the emission surface of the semiconductor chip to different extents. What is achieved in this way is that higher laser modes having significant intensities in the outer regions of the emission surface of the semiconductor chip experience, on account of the larger number of trenches in the outer region, higher losses than the central fundamental mode, the intensity maximum of which is situated in the inner of the emission surface of the semiconductor chip. In particular, a center of the emission surface of the semiconductor chip can be free of trenches.

In a further advantageous configuration, the at least one trench has a variable depth. In this case, the depth of the trench decreases from an outer region toward the inner of the emission surface of the semiconductor chip. By way of example, one or a plurality of trenches can be led from the inner of the emission surface of the semiconductor chip toward the outer regions of the emission surface of the semiconductor chip, wherein the depth of the trench increases from the inner side outward. Since the losses experienced by the propagating laser radiation upon traversing the at least one trench increase as the depth of the trench increases, the intensity of the losses can be varied locally by the setting of the depth of the at least one trench. By means of a larger depth of the at least one trench in the outer regions of the emission surface of the semiconductor chip in comparison with the inner of the emission surface of the semiconductor chip, higher laser modes experience greater losses than the central fundamental mode.

The above-described possibilities for the local variation of the losses by means of the trenches introduced into the cap layer region, in particular the number, the form and the depth of the trenches, can also be combined with one another. By way of example, both the number and the depth of the trenches can decrease from the outer regions of the emission surface of the semiconductor chip toward the inner of the emission surface of the semiconductor chip. Alternatively, by way of example, the depth of the trenches can increase from the inner of the emission surface of the semiconductor chip toward the outer regions. It is thus possible to increase the losses of the higher laser modes in such a way that the semiconducting disk laser commences oscillation only in the lateral fundamental mode.

Identical or identically acting constituent parts are provided with the same reference symbols in the figures. The constituent parts illustrated and also the size relationships of the constituent parts among one another should not be regarded as true to scale.

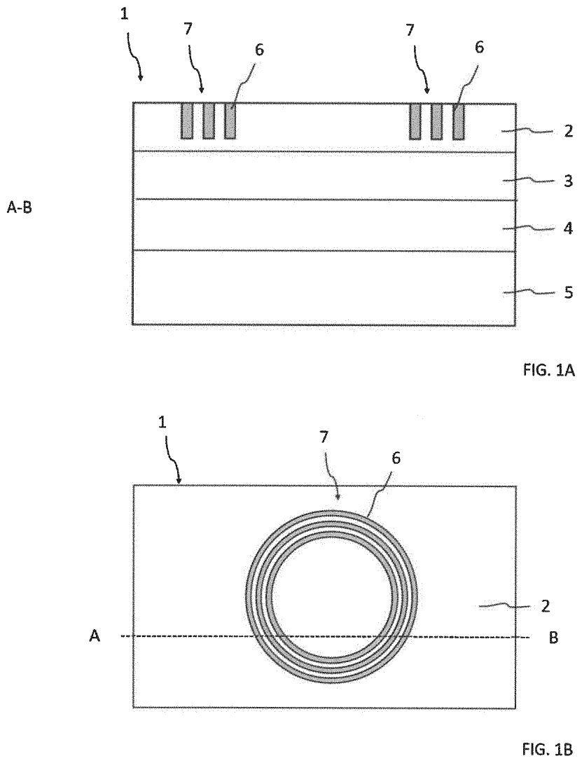

FIGS. 1A and 1B illustrate a first exemplary embodiment of a semiconductor disk chip. FIG. 1A shows a cross section along the line A-B of the plan view illustrated in FIG. 1B.

The semiconductor disk chip has a cap layer 2, a periodic gain structure (RPG) 3, a Distributed Bragg reflector (DBR) 4 and a substrate 5, from top to bottom direction of FIG. 1.

The Periodic gain structure (RPG) 3 of the semiconductor disk chip is provided for generating laser radiation, and can be, in particular, a single or multiple quantum well structure.

In the exemplary embodiment illustrated, the top layer 2 has structured regions 7. The structured regions 7 are formed exclusively in the top layer 2.

The structured regions 7 comprise a plurality of trenches 6 extending from the outer of the emission surface of the semiconductor chip to the inner of the emission surface of the semiconductor chip.

The trenches 6 preferably have a various depth. However, the deepest trench of the trenches 6 preferably extend into the cap layer 2 but do not extend into the periodic gain structure (RPG) 3. Therefore, the depth of the trenches 6 is relative to the thickness of the cap layer 2.

The width of the trenches is preferably between 1 μm and 4 μm inclusive, for example, 2 μm.

The trenches 6 are concentric patterns. The trenches 6 extend from outer regions of the emission surface of the semiconductor chip into the inner of the emission surface of the semiconductor chip with the same centroid but with different extents. The outer concentric patterns, which has the largest extents, for example, is 130 μm. The inner concentric patterns, which has the smallest extents, should be larger than the size of the fundamental mode on the surface of the semiconductor chip, for example, 120 μm. In this case, the region of the fundamental mode on the surface of the semiconductor chip is free of trenches 6. The trenches 6 can be arranged periodically, in particular, that is to say that they have identical distances from one another.

What is achieved by the arrangement of the trenches 6 is that the lateral fundamental mode, upon propagating vertically to cap layer 2, experiences lower losses than higher laser modes. This is based on the fact that the laser radiation propagating has to traverse through a larger number of trenches 6 in the outer regions than in the inner regions of the emission surface of the semiconductor chip, and consequently, higher laser modes experience comparatively high losses. By contrast, the influence of the trenches 6 on the lateral fundamental mode having an intensity maximum is only low.

The losses experienced by a circulating laser mode upon traversing the structured regions 7 can be influenced, in particular, by the spatial arrangement and the number of the trenches 6. Furthermore, in particular, the depth and the form of the sidewalls of the trenches 6 also influence the energy loss of the laser mode upon traversing the trenches. The energy loss upon traversing the trenches is substantially brought about by way of scattering of the laser radiation. Preferably, the trenches 6 are not filled with a material that is absorbent with respect to the laser radiation; in particular, the trenches 6 can be free of solid material and contain air, for example. Although the modes propagating can also be influenced by absorbent structures, structures having only insignificant absorption have the advantage that only a small heat input into the semiconductor body 1 takes place.

The trenches 6 can be produced in the semiconductor body 1 by means of an etching method, in particular. In this case, known methods of photolithography can be used for targeted structuring.

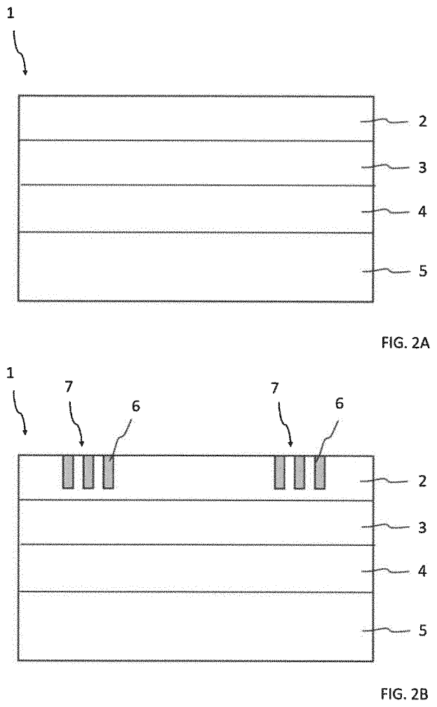

FIGS. 2A to 2B illustrate a method for producing an exemplary embodiment of a semiconductor disk chip on the basis of schematically illustrated intermediate steps.

As illustrated in FIG. 2A, firstly the semiconductor layer sequence of the semiconductor disk chip is grown onto a substrate 5. The semiconductor layers are preferably grown epitaxially, for example, by means of MOCVD. A cap layer 2, a periodic gain structure (RPG) 3 and a Distributed Bragg reflector (DBR) 4 are deposited successively onto the substrate 5.

The semiconductor layer sequence of the semiconductor disk chip can be based on a III-V compound semiconductor material, in particular. Depending on the wavelength of the semiconductor disk laser, arsenide, phosphide or nitride compound semiconductor materials, for example, can be used. In this case, the III-V compound semiconductor material need not necessarily have a mathematically exact composition according to one of the above formulae. Rather, it can comprise one or a plurality of dopants and also additional constituents which substantially do not change the physical properties of the material. For the sake of simplicity, however, the above formulae only include the essential constituents of the crystal lattice, even if these can be replaced in part by small amounts of further substances.

In this case, the material selection is effected on the basis of the desired emission wavelength of the semiconductor laser. The substrate 5 is selected on the basis of the semiconductor layer sequence, which is preferably to be grown epitaxially, and can be, in particular, a GaAs, GaN or silicon substrate.

The active layer 3 can be composed of a plurality of individual layers, in particular, a single or multiple quantum well structure. In this case, the designation quantum well structure encompasses any structure in which charge carriers experience a quantization of their energy states as a result of confinement. In particular, the designation quantum well structure does not include any indication about the dimensionality of the quantization. It therefore encompasses, inter alia, quantum wells, quantum wires and quantum dots and any combination of these structures.

In the intermediate step illustrated in FIG. 2B, a structured region 7 has been produced in the cap layer 2 by trenches 6 having been etched into the cap layer 2. The trenches 6 can be formed, for example, as in the case of the exemplary embodiment illustrated in FIGS. 1A and 1B.

As in the case of the exemplary embodiment illustrated in FIG. 1, the trenches 6 are concentric patterns, for example, concentric rings. The trenches 6 extend from outer regions of the emission surface of the semiconductor chip into the inner of the emission surface of the semiconductor chip with the same centroid, but with different diameters. The diameter of the concentric rings decreases from the outer regions of the structured region 7 to the structured region 7.

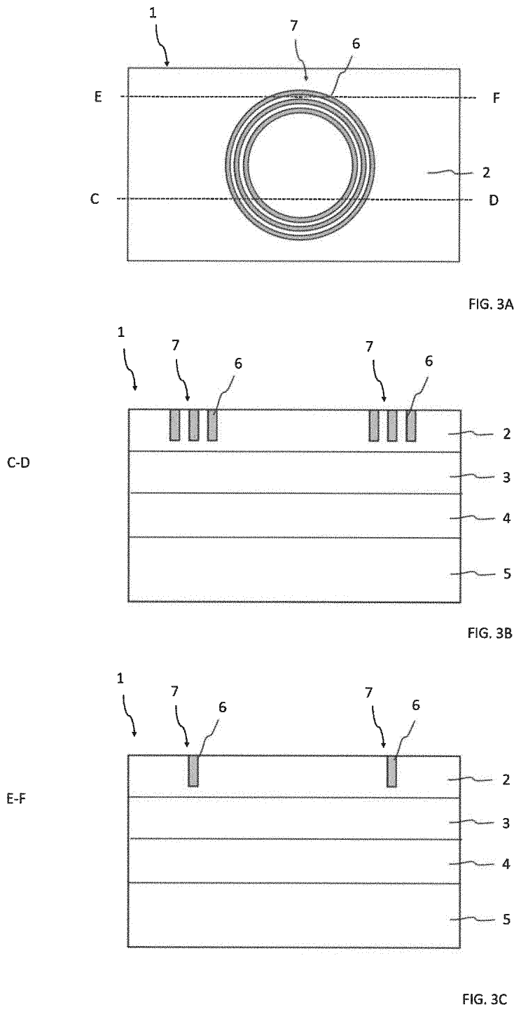

FIG. 3B shows a section through the surface of the semiconductor disk chip along the line C-D in the outer region of the emission surface of the semiconductor chip. The sectional view together with FIG. 3A illustrate the fact that the laser radiation has to pass a plurality of trenches 6 upon propagating in the emission direction in the outer region of the emission surface of the semiconductor chip.

The section along the line E-F, as illustrated in FIG. 3C together with FIG. 3A illustrate the fact that the laser radiation only has to pass one trench 6, by contrast, upon propagating in the inner region of the emission surface of the semiconductor chip. As can be discerned in the plan view in FIG. 3A, the center of the emission surface of the semiconductor chip is even free of trenches 6. By virtue of the fact that the number of trenches 6 which the laser radiation has to pass decreases from the outer toward the inner of the emission surface of the semiconductor chip, higher laser modes, upon propagating in the emission direction, experience higher losses than the lateral fundamental mode of the laser radiation. The number, the lateral extent and the depth of the trenches 6 can be optimized, for example, by simulation calculations in such a way that a desired mode profile of the laser radiation is obtained.

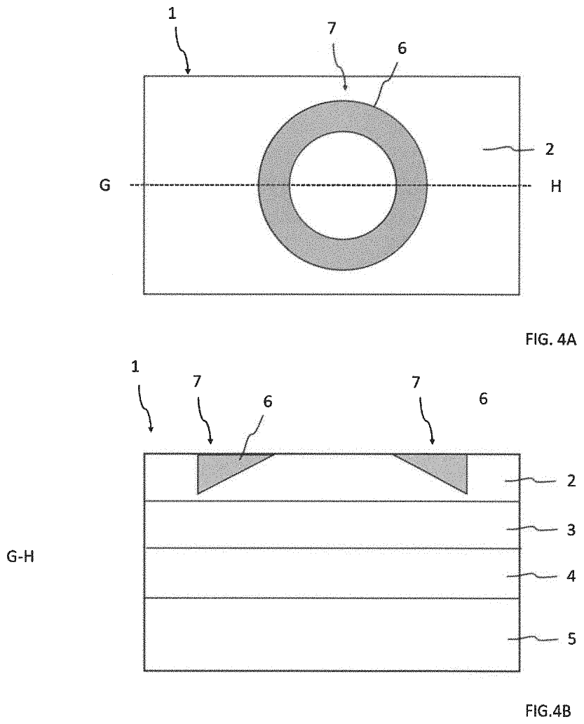

FIGS. 4A to 4B show a further exemplary embodiment of the structured region 7 in the cap layer 2. In contrast to the exemplary embodiments illustrated previously, in this exemplary embodiment only a single trench 6 is produced in the cap layer 2. In order to obtain a local variation of the losses of the laser modes in the direction perpendicular to the emission direction, the depth of the trench 6 varies from the outer of the emission surface of the semiconductor chip to the inner of the emission surface of the semiconductor chip.

The trench 6 has a comparatively large depth in the outer region of the emission surface of the semiconductor chip.

By contrast, the trench 6 has only a comparatively small depth in the inner region of the emission surface of the semiconductor chip.

The depth profile of the trench 6 along its longitudinal direction along the line G-H is illustrated in FIG. 4B. By virtue of the fact that the depth of the trench increases from the inner of the emission surface of the semiconductor chip toward the outer of the emission surface of the semiconductor chip, the laser modes upon propagating in the emission direction experience greater losses at the outer of the emission surface of the semiconductor chip than at the inner of the emission surface of the semiconductor chip. As in the previous exemplary embodiments, the propagation of the lateral fundamental mode having an intensity maximum in the inner of emission surface of the semiconductor chip is fostered in this way. In particular, single-mode operation of the semiconductor disk laser can be achieved in this way.

The local variation of the etching depth during the production of the trench 6 can be effected, for example, by proportional transfer of a photoresist layer in a sputtering or etching step with suitable selectivity.

The above-described possibilities for the local variation of the losses of the laser modes by local variation of the number of trenches, the depth of the trenches or the form of the sidewall of the trenches can, of course, be combined with one another.

The invention is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or exemplary embodiments.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### List of Reference Symbols:

1 Semiconductor body
2 cap layer
3 Periodic gain structure (RPG)
4 Distributed Bragg reflector (DBR)
5 Substrate
6 Trench
7 Structured region

1. A semiconductor disk chip comprising:
a cap layer having at least one structured region for mode selection;
a periodic gain structure:
a Distributed Bragg reflector; and
a substrate,
wherein the structured region is structured in such a way that a lateral fundamental mode of the laser radiation experiences lower losses than radiation of higher laser modes, the at least one structured region comprises at least one trench extending into the cap layer to a depth not greater than a thickness of the cap layer, and wherein the depth decreases from an outer region of an emission surface of the semiconductor chip in a direction of an inner of the emission surface of the semiconductor chip.

2. The semiconductor disk chip according to claim 1, wherein the at least one structured region is formed exclusively in the cap layer.

3. The semiconductor disk chip according to claim 1, wherein the at least one trench has a width of between 1 μm and 4 μm.

4. The semiconductor disk chip according to claim 1, wherein the at least one trench extends from the outer region of the emission surface of the semiconductor chip in a direction of the inner of the emission surface of the semiconductor chip.

5. The semiconductor disk chip according to claim 4, wherein the at least one trench comprises a plurality of trenches that extend from an outer region of the emission surface of the semiconductor chip into the inner of the emission surface of the semiconductor chip to different extents.

6. The semiconductor disk chip according to claim 5, wherein a number of trenches passed by the laser radiation propagating decreases from the outer region toward the inner region of the emission surface of the semiconductor chip.

7. The semiconductor disk chip according to claim 1, wherein a central region of the emission surface of the semiconductor chip is free of trenches.

8. The semiconductor disk chip according to claim 1, wherein the at least one trench has sidewalls having a variable form.

9. The semiconductor disk chip according to claim 8, wherein a depth of the sidewalls decreases from the outer region toward the inner region of the emission surface of the semiconductor chip.
